(19) United States
(12) Patent Application Publication
(10) Pub. No.: US 2006/0094228 A1
(43) Pub. Date: May 4, 2006

(54) Structure and method for contact pads having an overcoat-protected bondable metal plug over copper-metallized integrated circuits

(76) Inventors: Lei Li, Richardson, TX (US); Edgardo R. Hortaleza, Garland, TX (US)

Correspondence Address: TEXAS INSTRUMENTS INCORPORATED, P O BOX 655474, M/S 3999, DALLAS, TX, 75265, US

(21) Appl. No.: 11/259,547

(22) Filed: Oct. 26, 2005

Related U.S. Application Data
(62) Division of application No. 10/806,519, filed on Mar. 23, 2004.

(51) Int. Cl. H01L 21/4763

(52) U.S. Cl. 438/622

(57) ABSTRACT

A metal structure for a contact pad of an integrated circuit (IC), which has copper interconnecting metallization (311). A portion (301) of this metallization is exposed to provide a contact pad to the IC. A conductive barrier layer (330) is positioned on the exposed portion o the copper metallization. A plug (350) of bondable metal, preferably aluminum between about 0.4 and 1.4 μm thick, is positioned on the barrier layer. A protective overcoat layer (320) surrounds the plug and has a thickness (320b) so that the exposed surface (322) of the plug lies at or below the exposed surface (320a) of the overcoat layer. Optionally, a portion (321) of the overcoat layer between about 0.1 and 0.3 μm wide may overlap the perimeter of the plug.

### FIELD OF THE INVENTION

The present invention is related in general to the field of electronic systems and semiconductor devices and more specifically to bond pad structures and fabrication methods of copper metallized integrated circuits.

### DESCRIPTION OF THE RELATED ART

In integrated circuits (IC) technology, pure or doped aluminum has been the metallization of choice for interconnection and bond pads for more than four decades. Main advantages of aluminum include easy of deposition and patterning. Further, the technology of bonding wires made of gold, copper, or aluminum to the aluminum bond pads has been developed to a high level of automation, miniaturization, and reliability.

In the continuing trend to miniaturize the ICs, the RC time constant of the interconnection between active circuit elements increasingly dominates the achievable IC speed-power product. Consequently, the relatively high resistivity of the interconnecting aluminum now appears inferior to the lower resistivity of metals such as copper. Further, the pronounced sensitivity of aluminum to electromigration is becoming a serious obstacle. Consequently, there is now a strong drive in the semiconductor industry to employ copper as the preferred interconnecting metal, based on its higher electrical conductivity and lower electromigration sensitivity. From the standpoint of the mature aluminum interconnection technology, however, this shift to copper is a significant technological challenge.

Copper has to be shielded from diffusing into the silicon base material of the ICs in order to protect the circuits from the carrier lifetime killing characteristic of copper atoms positioned in the silicon lattice. For bond pads made of copper, the formation of thin copper(I)oxide films during the manufacturing process flow has to be prevented, since these films severely inhibit reliable attachment of bonding wires, especially for conventional gold-wire ball bonding. In contrast to aluminum oxide films overlying metallic aluminum, copper oxide films overlying metallic copper cannot easily be broken by a combination of thermocompression and ultrasonic energy applied in the bonding process. As further difficulty, bare copper bond pads are susceptible to corrosion.

In order to overcome these problems, the semiconductor industry adopted a structure to cap the clean copper bond pad with a layer of aluminum and thus re-construct the traditional situation of an aluminum pad to be bonded by conventional gold-wire ball bonding. The described approach, however, has several shortcomings. First, the fabrication cost of the aluminum cap is higher than desired, since the process requires additional steps for depositing metal, patterning, etching, and cleaning. Second, the cap must be thick enough to allow reliable wire bonding and to prevent copper from diffusing through the cap metal and possibly poisoning the IC transistors.

Third, the aluminum used for the cap is soft and thus gets severely damaged by the markings of the multiprobe contacts in electrical testing. This damage, in turn, becomes so dominant in the ever decreasing size of the bond pads that the subsequent ball bond attachment is no longer reliable. Finally, the elevated height of the aluminum layer over the surrounding overcoat plane enhances the risk of metal scratches and smears. At the tight bond pad pitch of many high input/output circuits, any aluminum smear represents an unacceptable risk of shorts between neighbor pads.

### SUMMARY OF THE INVENTION

A need has therefore arisen for a metallurgical bond pad structure suitable for ICs having copper interconnection metallization which combines a low-cost method of fabricating the bond pad structure, a perfect control of up-diffusion, a risk elimination of smearing or scratching, and a reliable method of bonding wires to these pads. The bond pad structure should be flexible enough to be applied for different IC product families and a wide spectrum of design and process variations. Preferably, these innovations should be accomplished while shortening production cycle time and increasing throughput, and without the need of expensive additional manufacturing equipment.

One embodiment of the invention is a metal structure for a contact pad of an integrated circuit (IC), which has copper interconnecting metallization. A portion of this metallization is exposed to provide a contact pad to the IC. A conductive barrier layer positioned on the exposed portion of the copper metallization. A plug of bondable metal, preferably aluminum between about 0.4 and 1.4 μm thick, is positioned on the barrier layer. A protective overcoat layer surrounds the plug and has a thickness so that the exposed surface of the plug lies at or below the exposed surface of the overcoat layer. Optionally, a portion of the overcoat layer between about 0.1 and 0.3 μm wide may overlap the perimeter of the plug.

Another embodiment of the invention is a wafer-level method of fabricating a metal structure for a contact pad of an integrated circuit, which has copper interconnecting metallization. The method comprises the steps of chemically-mechanically polishing the wafer to expose the patterned contact pad areas of the copper metallization embedded in insulating material. A barrier metal layer is then deposited over the wafer including the exposed copper metallization. Next, a bondable metal layer (preferably aluminum) is deposited over the barrier layer in a thickness sufficient for wire ball bonding. Next, both deposited metal layers are patterned so that the layer portions outside the contact pad areas are removed and the layer portions over the contact pad areas remain to form a bondable metal plug over each contact pad. A layer of protective overcoat is then deposited over the wafer, including the metal plugs of the patterned layer portions. The overcoat layer has a thickness so that the exposed surface of the overcoat layer lies at or above the exposed surface of the bondable metal layer. Finally, windows are opened in the overcoat layer so that the bondable metal plugs are exposed.

Embodiments of the present invention are related to wire-bonded IC assemblies, semiconductor device packages, surface mount and chip-scale packages. It is a technical advantage that the invention offers a low-cost method of reducing the risk of aluminum-smearing or -scratching and electrical shorting between contact pads. The assembly yield of high input/output devices can thus be significantly improved. It is an additional technical advantage that the invention facilitates the shrinking of the pitch of chip contact pads without the risk of yield loss due to electrical shorting. Further technical advantages include the opportunity to scale the assembly to smaller dimensions, supporting the ongoing trend of IC miniaturization.

The technical advantages represented by certain embodiments of the invention will become apparent from the following description of the preferred embodiments of the invention, when considered in conjunction with the accompanying drawings and the novel features set forth in the appended claims.

### BRIEF DESCRIPTION OF THE DRAWINGS

FIG. 1 depicts a schematic cross section of a contact pad of an integrated circuit (IC) with copper metallization according to known technology. The bondable metal is added as an additional layer elevated over the wafer surface.

FIG. 2 illustrates a schematic cross section of two wire-bonded contact pads of a copper-metallized IC in known technology. The elevated bondable metal layers have been scratched and smeared, causing an electrical short.

FIG. 3 is a schematic cross section of an embodiment of the invention depicting a contact pad of an IC with copper metallization, wherein the contact pad has a bondable metal plug.

FIG. 4 is a schematic cross section of the bond pad metallization according to the invention, with a ball bond attached to the bondable metal plug.

FIG. 5 is a block diagram of the device fabrication process flow according to another embodiment of the invention.

### DETAILED DESCRIPTION OF THE PREFERRED EMBODIMENTS

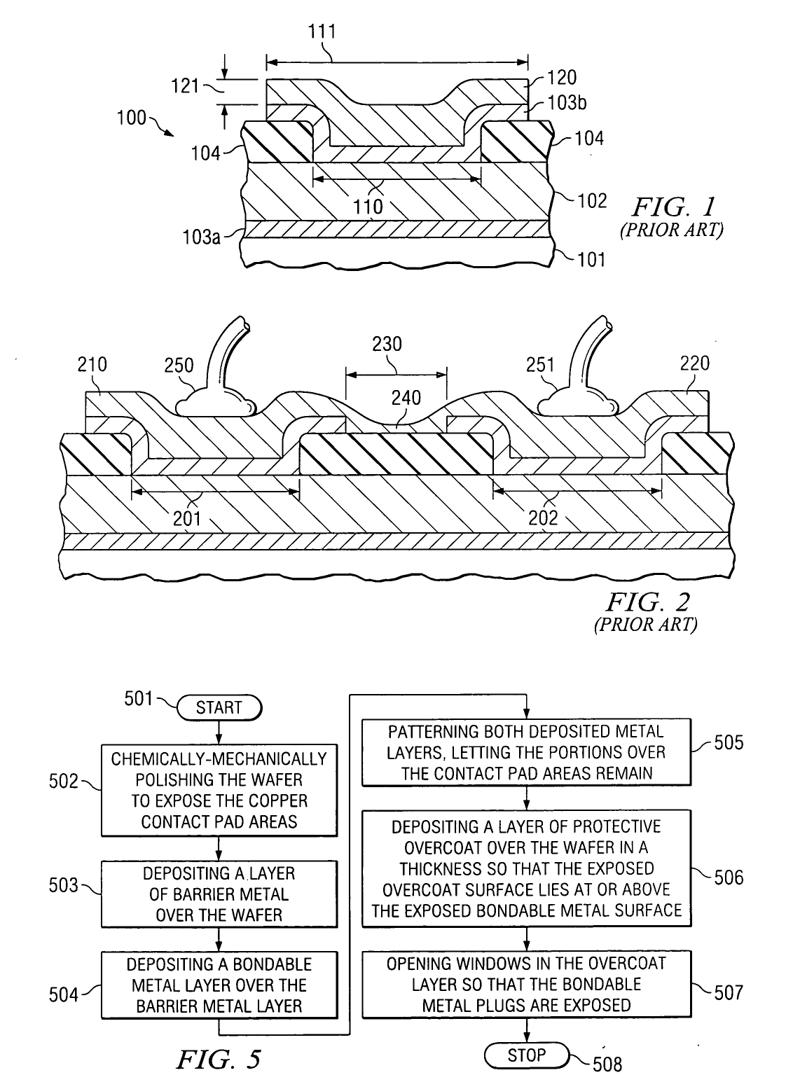

The technical advantages offered by the invention can be best appreciated by comparing an embodiment of the invention with the conventional method of wire-bonding a contact pad of an integrated circuit (IC) chip, which uses copper as interconnecting metal. An example of a conventional structure is depicted in FIG. 1. In the schematic cross section of an IC contact pad generally designated 100, 101 is an intra-level dielectric, which may consist of silicon dioxide, a low-k dielectric, or any other suitable insulator customarily used in ICs. 102 represents the top level IC copper metallization (thickness typically between 200 and 500 nm, contained by barrier layers 103a and 103b (typically tantalum nitride, typically 10 to 30 nm thick) from diffusing into other IC materials. In the essentially moisture-impermeable overcoat layer 104 (typically between 500 to 1000 nm of silicon nitride, silicon oxynitride, or silicon dioxide, single-layered or multi-layered) is contact window 110, usually between 40 to 70 μm wide, which exposed the copper metallization 102 for establishing a contact. Barrier layer 103b overlaps overcoat 104 around the window perimeter to create a metallization width 111, which is thus larger than window 110 (typically about 45 to 75 μm diameter). The same width 111 holds for the bondable metal layer 120, which is aluminum or a copper-aluminum alloy. For reliable wire bonding, layer 120 has typically a thickness 121 between 700 and 1000 nm.

This considerable height 121 of the patterned aluminum layer 120 represents a substantial risk for accidental scratching or smearing of the aluminum. There are numerous wafer and chip handling steps in a typical assembly process flow after the aluminum patterning. The most important steps include back-grinding; transporting the wafer from the fab to the assembly facility; placing the wafer on a tape for sawing; sawing and rinsing the wafer; attaching each chip onto a leadframe; wire bonding; and encapsulating the bonded chip in molding compound. At each one of these process steps, and between the process steps, accidental scratching or smearing could happen.

An example is schematically indicated in FIG. 2, which is a cross section through two bonding pads 201 and 202 in close proximity (distance 230). The aluminum layer 210 of pad 201 and the aluminum layer 220 of pad 202 have been scratched so that the aluminum is smeared together at 240. As a consequence, the pads of bonds 250 and 251 form an electrical short.

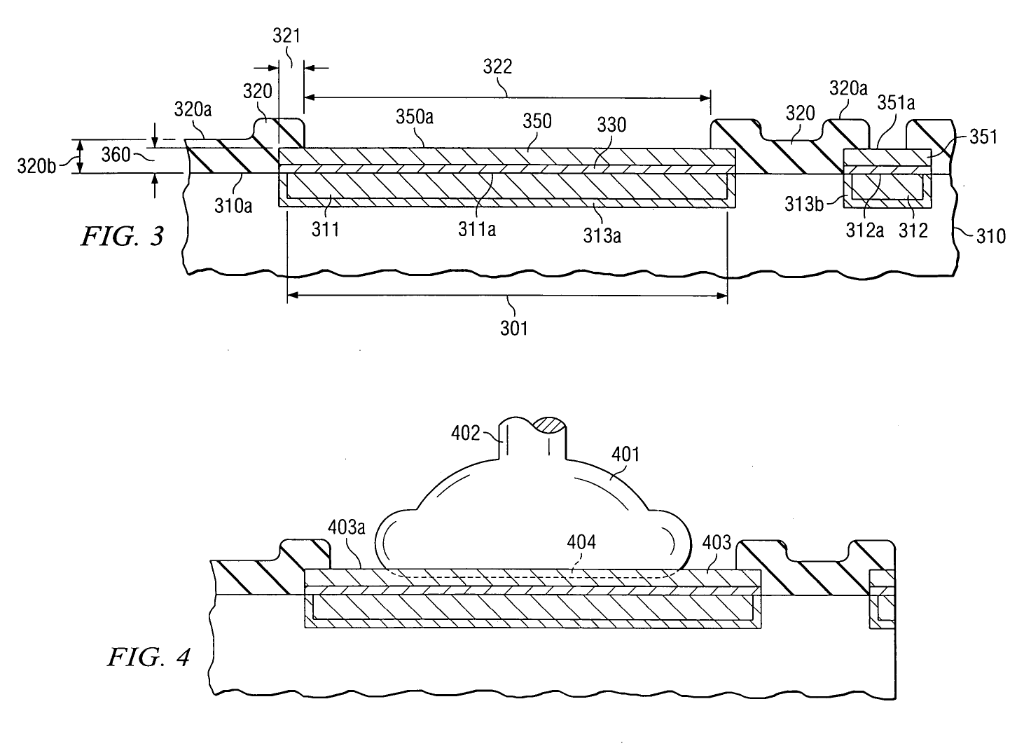

An embodiment of the invention is shown in FIG. 3, illustrating a schematic cross section of a portion 300 of a semiconductor wafer. The interlevel insulating material 310 is made, for instance, of low-k dielectric material, silicon dioxide, or a stack of dielectric materials. FIG. 3 further shows portions of the patterned top layer of the IC interconnecting metallization made of copper or a copper alloy, embedded in insulator 310. Illustrated is specifically the portion 311 of the copper layer intended to provide a contact pad, and portion 312 intended to anchor the scribe street. The thickness of the copper layer is preferably in the range from 0.2 to 0.5 μm. The copper metallization is contained by barrier layer 313a, and 113b respectively, from diffusing into insulator 310 or other integrated circuit materials; barrier layers 313a and 313b are preferably made of tantalum nitride and about 10 to 30 nm thick. The bond pad copper layer 311 has a width 301 (typically in the range from 30 to 60 μm).

As FIG. 3 indicates, the exposed surface (top surface) 311a of copper layer 311, and exposed surface (top surface) 312a of the scribe street metallization are at the same level as the top surface 310a of the dielectric material 310. The reason for this uniformity is the method of fabrication involving a chemical-mechanical polishing step (see below).

In order to establish low-resistance ohmic contact to the copper, one or more conductive barrier layers 330 are deposited over the copper, as indicated in FIG. 3. For a single layer, tantalum nitride is the preferred selection. For a couple of layers, the first barrier layer is preferably selected from titanium, tantalum, tungsten, molybdenum, chromium and alloys thereof; the layer is deposited over the exposed copper 311 with the intent to establish good ohmic contact to the copper by “gettering” the oxide away from the copper. A second barrier layer, commonly nickel vanadium, is deposited to prevent out diffusion of copper. The barrier layer has a thickness preferably in the range from 0.02 to 0.03 μm. In FIG. 3, barrier layer 330 is shown to have the same width 301 as copper metallization 311. While this is the preferred structure, there may be device designs, in which the barrier width is somewhat smaller or larger.

On top of the barrier layer 330 is a layer 350 of bondable metal, which has a thickness suitable for wire ball bonding. The preferred thickness ranges from about 0.4 to 1.4 μm. Because of this considerable thickness, layer 350 is often referred to as a plug. The bondable metal is preferably aluminum or an aluminum alloy, such as aluminum-copper alloy. In FIG. 3, the exposed surface of this plug is designated 350a. An aluminum layer 351 of the same thickness is shown in FIG. 3 over the scribe street metal 312.

Since the surfaces 310a and 311a are on a common level, as mentioned above, the combined thicknesses of barrier layer 330 and bondable plug 350 stick out geometrically above this common level; in FIG. 3, this combined height above the level is designated 360. In order to prevent any accidental scratching or smearing, a protective overcoat layer 320 is deposited (more detail see below). Preferred overcoat materials are practically moisture impermeable or moisture retaining, and mechanically hard; examples include one or more layers of silicon nitride, silicon oxynitride, silicon carbide, or a stack of insulating materials including polyimide. The overcoat has a thickness 320b in the range from 0.5 to 1.5 μm, preferably 1.0 μm. In FIG. 3, the exposed surface of overcoat layer 320 is designated 320a.

According to the invention, the deposited protective overcoat layer 320 has a thickness 320b and surrounds plug 350 so that the exposed surface 350a of plug 350 lies at or below the exposed surface 320a of overcoat layer 320. A window of width 322 is opened in overcoat 320 in order to expose surface 350a of plug 350. Preferably, width 322 is narrower than width 301 of plug 350; therefore, a portion (designated 321 in FIG. 3) of overcoat 320 may overlap the perimeter of plug 350. Analogous statements apply to the overcoat layer 320 relative to aluminum layer 351. Plug surface 350a, and layer surface 351a, are not elevated relative to the overcoat surface 320a; consequently, plug 350, and layer 351 respectively, are protected against accidental scratches, providing the undisturbed plug metal for reliable ball bonding.

The cross section of FIG. 4 illustrates schematically the contact pad of FIG. 3 after the chip has been singulated from the wafer in a sawing process (scribe street indicated by 410) and a ball bond has been attached. A free air ball 401 (preferably gold) of a metal wire 402 (preferably gold) is pressure-bonded to the undisturbed surface 403a of the plug 403 (preferably aluminum or an aluminum alloy). In the bonding process, intermetallic compounds 404 are formed in the contact region of ball and plug.

Another embodiment of the invention is a wafer-level method of fabricating a metal structure for a contact pad of an integrated circuit, which has copper interconnecting metallization. The process flow is displayed in the schematic block diagram of FIG. 5. The method, starting at step 501, polishes the wafer chemically-mechanically in step 502 in order to expose the patterned contact pad areas of the copper metallization embedded in insulating material.

In the next process step 503, a barrier metal layer is deposited over the wafer, including the exposed copper metallization. Preferred barrier metal choices include tantalum or tantalum nitride, and nickel vanadium; the preferred barrier layer thickness is between about 20 and 30 nm. In step 504, a bondable metal layer is deposited over the barrier layer in a thickness sufficient for wire ball bonding. Preferred bondable metal choices include aluminum and aluminum alloy, the preferred bondable meta layer thickness is between about 0.4 to 1.4 μm.

In the next process step 505, both deposited metal layers are patterned so that the layer portions outside the contact pad areas are removed and the layer portions over the contact pad areas remain in order to form a bondable metal plug over each of the contact pads.

In the next process step 506, a layer of protective overcoat is deposited over the wafer, including the metal plugs of the patterned layer portions formed in step 505. The overcoat preferably comprises one or more layers of silicon nitride, silicon oxy-nitride, silicon dioxide, silicon carbide, or other moisture-retaining compounds. The overcoat layer has a thickness so that the exposed surface of the overcoat layer lies at or above the exposed surface of the bondable metal layer. The preferred overcoat thickness ranges from about 0.6 to 1.5 μm.

In process step 507, windows are opened in the overcoat layer so that the bondable metal plugs are exposed. The windows may be sized so that an overcoat frame having a width between about 0.1 and 0.3 μm is left around the perimeter of the bond pad area, providing to the plug additional protection against accidental scratches. The method concludes with process step 508.

While this invention has been described in reference to illustrative embodiments, this description is not intended to be construed in a limiting sense. Various modifications and combinations of the illustrative embodiments, as well as other embodiments of the invention, will be apparent to persons skilled in the art upon reference to the description. It is therefore intended that the appended claims encompass any such modifications and embodiments.

1-14. (canceled)

15. A method of fabricating a wafer of integrated circuit chips having copper interconnecting metallization and contact Dads, comprising the steps of:
chemically-mechanically polishing said wafer to expose the contact pad areas of said copper metallization;
depositing a barrier metal layer over said wafer including said exposed copper metallization;
depositing a bondable metal layer over said barrier layer in a thickness sufficient for wire ball bonding;
patterning both said deposited metal layers so that the layer portions outside said contact pad areas are removed and the layer portions over said contact pad areas remain to form a bondable metal plug with a interior portion and a peripheral portion;
depositing a layer of protective overcoat over said wafer, including said metal plugs of said patterned layer portions;
opening windows in said overcoat layer so that the interior portion of said bondable metal plugs are exposed and the peripheral portion are covered by the overcoat layer.

16. The method according to claim 15 wherein said step of depositing a bondable metal layer includes depositing aluminum in the thickness range from about 0.4 to 1.4 μm.

17. The method according to claim 15 wherein said overcoat has a thickness in the range from about 0.6 to 1.5 μm.

18. The method according to claim 15 wherein said overcoat frame has a width between about 0.1 to 0.3 μm.

19. (canceled)

20. A method of fabricating a wafer having copper contact pads; comprising the steps of:
chemically-mechanically polishing the wafer to expose the contact pad;
depositing a barrier metal layer over said wafer;
depositing a bondable metal layer over the barrier layer;
patterning and etching both deposited metal layers to form bondable metal plugs over the contact pads each with a interior portion and a peripheral portion;
depositing a layer of protective overcoat over the wafer; and
opening windows in the overcoat layer so that the interior portion of said bondable metal plugs are exposed and the peripheral portion are covered by the overcoat layer.
